(19) United States
(12) Patent Application Publication
(10) Pub. No.: US 2014/0175657 A1
(43) Pub. Date: Jun. 26, 2014

(54) METHODS TO IMPROVE LASER MARK CONTRAST ON DIE BACKSIDE FILM IN EMBEDDED DIE PACKAGES

(71) Applicants: Mihir A. Oka, Chandler, AZ (US); Rahul N. Manepalli, Chandler, AZ (US); Dingying Xu, Maricopa, AZ (US); Yosuke Kanaoka, Tsukuba (JP); Sergei L. Voronov, Chandler, AZ (US); Dong Hai Sun, Chandler, AZ (US)

(72) Inventors: Mihir A. Oka, Chandler, AZ (US); Rahul N. Manepalli, Chandler, AZ (US); Dingying Xu, Maricopa, AZ (US); Yosuke Kanaoka, Tsukuba (JP); Sergei L. Voronov, Chandler, AZ (US); Dong Hai Sun, Chandler, AZ (US)

(21) Appl. No.: 13/725,539

(22) Filed: Dec. 21, 2012

(51) Int. Cl. H01L 23/48; H01L 21/02

(52) U.S. Cl. CPC H01L 23/48; H01L 21/02
USPC 257/773; 438/401

(57) ABSTRACT

Apparatus including a die including a device side with contact points; and a build-up carrier disposed on the device side of the die; and a film disposed on the back side of the die, the film including a markable material including a mark contrast of at least 20 percent. Method including forming a body of a build-up carrier adjacent a device side of a die; and forming a film on a back side of the die, the film including a markable material including a mark contrast of at least 20 percent. Apparatus including a package including a microprocessor disposed in a carrier; a film on the back side of the microprocessor, the film including a markable material including a mark contrast of at least 20 percent; and a printed circuit board coupled to at least a portion of the plurality of conductive posts of the carrier.

### BACKGROUND

1. Field

Packaging for microelectronic devices.

2. Description of Related Art

Microelectronic packaging technology, including methods to mechanically and electrically attach a silicon die (e.g., a microprocessor) to a substrate or other carrier continues to be refined and improved. Bumpless Build-Up Layer (BBUL) technology is one approach to a packaging architecture. Among its advantages, BBUL eliminates the need for assembly, eliminates prior solder ball interconnections (e.g., flip-chip interconnections), reduces stress on low-k interlayer dielectric of dies due to die-to-substrate coefficient of thermal expansion (CTE mismatch), and reduces package inductance through elimination of core and flip-chip interconnect for improved input/output (I/O) and power delivery performance.

Portable electronics such as mobile phones, personal digital assistance, and digital cameras are becoming more compact while their functionalities increase. The demand for more features in processing power, coupled with a need for smaller integrated circuit package outlines has driven assembly technologies into such electronics. Examples include flip-chip or direct chip attach. Embedded die packages (e.g., BBUL packages) is a packaging technology that provides many advantages over flip-chip or direct chip attach technologies. Such advantages include cost, z-height, improved bump pitch scalability and reduction in x-, y-form factor.

Manufactures and consumers of portable electronic devices desire that the chip or package used in a device contain identification marks such as company logos, pin orientation, manufacturing history such as lot number, time/date traceability, etc., so that a particular chip and/or package can be identified. Traditionally, identification marks are placed on the exterior package with laser marking in wafer form. Miniaturization of devices makes the traditional package disappear and leaves little room for the traditional identification marks.

Die backside films are used in packaging technologies, including packaging technologies related to mobile phones and tablet platforms. These films provide many functionalities such as die crack protection as well as a laser markable surface for unit level identification. To provide quality identification marks on a die backside film, the mark should be readable. This provides the highest comfort level in a manufacturing plant as it can always be verified on a production floor if needed. For identification marks to be readable, a suitable level of contrast is required for both humans and machine vision systems. In die embedded package technologies such as BBUL, a die backside film is used to bond a die to panels prior to substrate build up. After depaneling and separation of a package from a sacrificial core, however, the die backside film surface has been found to no longer be a suitable laser markable surface due principally to the thermal mechanical process operations used during assembly of a BBUL package. As a result, a viable strategy for maintaining unit level identification in BBUL packaging does not exist.

### BRIEF DESCRIPTION OF THE DRAWINGS

FIG. 1 shows a cross-sectional view one embodiment of a portion of a microelectronic package including a die embedded in a build-up carrier.

FIG. 2 shows a cross-sectional exploded side view of a sacrificial substrate with sacrificial copper foils attached to opposite sides thereof.

FIG. 3 show the structure of FIG. 2 following the introduction of contacts on the copper foils and a dielectric layer over the contacts in a process of forming one portion of the carrier.

FIG. 4 shows the structure of FIG. 3 following the introduction of dice on opposite sides of the structure.

FIG. 5 shows the structure of FIG. 4 following the introduction of dielectric material on the dice.

FIG. 6 shows the structure of FIG. 5 following the opening of vias in the dielectric layers.

FIG. 7 shows the structure of FIG. 6 following the introduction of a conductive material in the vias and the patterning of a conductive layer or line on the dielectric.

FIG. 8 shows the structure of FIG. 7 following the introduction of successive layers of dielectric material and conductive material (second layer) on opposite sides of the structure.

FIG. 9 shows the structure of FIG. 8 following the introduction of successive layers of dielectric material and conductive material (third and fourth layers) on opposite sides of the structure with the ultimate conductive material layer defined by pads or lands and a dielectric material on the ultimate conductive material layer.

FIG. 10 shows the structure of FIG. 9 following the formation of openings to respective ones of the pads or lands of the ultimate conductive material layer on opposite sides of the structure.

FIG. 11 shows the structure of FIG. 14 after separation of the structure into individual packages and undergoing an electromagnetic radiation marking process.

FIG. 12 illustrates a schematic illustration of a computing device.

### DETAILED DESCRIPTION

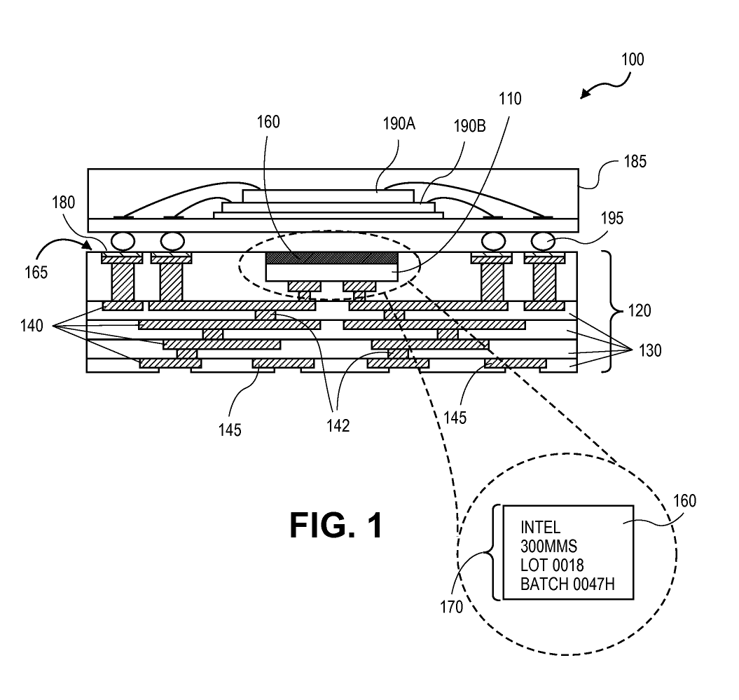

FIG. 1 shows a cross-sectional view of a microelectronic package according to one embodiment. As illustrated in FIG. 1, microelectronic package 100 utilizes bumpless build-up layer (BBUL) technology. Microelectronic package 100 includes carrier 120 (a build-up carrier) and die 110, such as a microprocessor die, embedded in carrier 120 device side down (as viewed). Die 110 and carrier 120 are in direct physical contact with each other (e.g., there are no solder bumps connecting die 110 to carrier 120).

In one embodiment, die 110 is a silicon die or the like having a thickness of approximately 150 micrometers (μm). In another example, die 110 can be a silicon die or the like that has a thickness less than 150 μm such as 50 μm to 150 μm. It is appreciated that other thicknesses for die 110 are possible. In another embodiment, die 110 may be a through silicon via (TSV) die with contacts on a back side of die 110.

Referring to FIG. 1, carrier 120 includes multiple build-up layers including dielectric layers 130 (four shown) of, for example, ABF and conductive layers 140 (four shown) of, for example, copper or a copper alloy (connected with conductive vias 142 or the like) that provide connectivity to the die (power, ground, input/output, etc.) through lands 145 that define the ultimate conductive layer 140 (i.e., the lower most conductive layer as viewed). Die 110 is directly connected to lands 145 or conductive vias of carrier 120 at its device side.

FIG. 1 also shows contacts 180 on surface 165 (top surface as viewed) of carrier 120. Contacts 180 are connected to one or more conductive layers 140 of carrier 120. Contacts 180 provide an additional routing opportunity (additional to posts 150) to route signals to or from microelectronic package 100. Contacts 180 allow additional interconnect points for the package as well as contact points for a second device, such as a memory device or microprocessor (possibly encompassed in a package) to be electrically connected to carrier 120 to form microelectronic package 100 or a package-on-package (“POP”) structure. FIG. 1 shows package 185 including die 190A and die 190B connected to carrier 120 through solder connections 195.

As shown in FIG. 1, dielectric material surrounds the lateral side walls of die 110 of microelectronic package 100. Overlying a backside of die 110 is die backside film (DBF) 160. In one embodiment, DBF 160 is a markable material comprising a mark contrast of at least 20 percent. Representatively, DBF 160 is a multicomponent composition including a polymer matrix, a filler, a pigment/dye, an adhesion promoter, and a solvent. In one embodiment, the polymer matrix includes a resin such as an epoxy, e.g., a multifunctional epoxy and a hardener (e.g., phenol Novolac) and optionally a flexibilizer. The resin and hardener generally dictate the overall thermomechanical properties of the film. The flexibilizer generally provides flexibility to the material.

In one embodiment, the filler material includes particles having a mean particle size on the order of 100 nanometers (nm) or less. In another embodiment, a mean particle size of filler material is less than 100 nm. In a further embodiment, a mean particle size of filler material is 50 nm or less. Without wishing to be bound by theory, it is believed that the filler and its particle size effects a modulus of the material and its markability properties, specifically with regard to laser marking In one embodiment, the filler, such as a silica nanometer filler has a mean particle size of 50 nm and is present in an amount of 20 weight percent to 50 weight percent of the total material composition. In another embodiment, the filler is present in an amount of 20 weight percent to 40 weight percent. Again without wishing to be bound by theory, it is believed that the presence of the nanometer silica enhances contrast due to the increased surface area of silica particles relative to, for example, micron size particles thereby significantly increasing scattering in a laser marked region versus an underlying background. As described herein, laser marked contrast refers to the gray value differential achieved by two dimensional (2D) ID reader illumination light scatterings from a mark and no scattering from ambient film surface. In a laser marking process, it is believed that a laser, such as a 2D ID electromagnetic radiation source (e.g., neodymium-doped yttrium aluminum garnet (Nd:YAG) laser) burns the organic material in DBF 160 thereby exposing the filler material. In one embodiment, a marking process is based on thermal laser ablation with an ablation threshold fluence below ablation of the filler material (e.g., silica particles) and above an ablation of the organic polymer. As a result of ablation, the organic polymer is ablated but light scattering filler material (e.g., silica particles) remains integrated in the film. The filler material provides the light contrast.

The presence of the nanometer silica particles also tends to modulate a film etch rate in processing steps such as a wet blast process used to separate a completed package from a sacrificial substrate. The modulation in film etch rate is seen in a greater etch rate selectivity for a die backside film compared to organic layers in an embedded package.

In one embodiment, DBF 160 includes a organic dye with a maximum light absorption or lambda max in the visible wavelength region. Generally, a dye or a pigment is a colorant that is used in DBF 160 to provide laser mark contrast. Examples of organic dyes include an organic dye with reactive functional groups, e.g., amine/epoxy/azo functional groups may also act as a curing accelerator.

In one embodiment, a composition of DBF 160 may also include an adhesion promoter and a solvent.

The following is a representative embodiment of a suitable DBF for BBUL applications including suitable markability (“BBUL DBF”).

| Raw Materials | Function | Content |
|---|---|---|
| Polyimide/Acrylic/Epoxy/Epoxy- | Base resin | 15-25 wt % |
| Acrylate resin | | |
| Amine/Anhydride/Phenolic resin | Hardener | 15-25 wt % |
| Polybutadiene/high impact | Flexibilizer | 10-20 wt % |
| polystyrene (HIPS)/Acrylic rubber | | |
| Organic dye (with absorption max | Laser marking | 3-10 wt % |
| in visible wavelength region) | | |
| Inorganic filler (e.g., silica | Stiffness/thermal | 20-50 wt % |
| filler) | expansion | |
| | control/moisture | |
| | absorption control | |

The BBUL DBF uses filler particles (silica particles) having a particle size significantly smaller than filler particles in prior art DBF (e.g., 100 nm or 50 nm versus 0.5 μm). The BBUL DBF also uses a higher percentage of dye (7 percent versus 3.5 percent). It has been found that a dye tends to interact with other chemicals during the package build-up process and may also be physically transferred (e.g., physically transferred to a sacrificial substrate on which the package is formed). To account for any loss of -dye due to interaction or transfer of the dye, in one embodiment, a greater weight percentage of dye is used (e.g., a percentage greater than the present in prior art DBF. Representative amounts of dye are 5 percent to 10 percent with the amount of the dye effecting laser markability not contrast. In another embodiment, functional groups such as amine (e.g., —NH₂, —NHR) and hydroxyl (—OH) groups can be appended to a dye to make the dye more reactive with other DBF components (e.g., resin, filler, elastomer) to reduce a loss of the dye. In that instance, a lesser amount of dye can be utilized to achieve acceptable markability (e.g., 3.5 percent or less).

An inset of FIG. 1 shows a view of the top surface of DBF 160 (i.e., the surface opposite die 110). In this embodiment, DBF 160 has been marked using a laser marking technique to indicate a source of die 110, a size of the die and a lot and batch number. It is appreciated that any marking may be any type of marking that identifies die 110 by human or machine-readable characteristics.

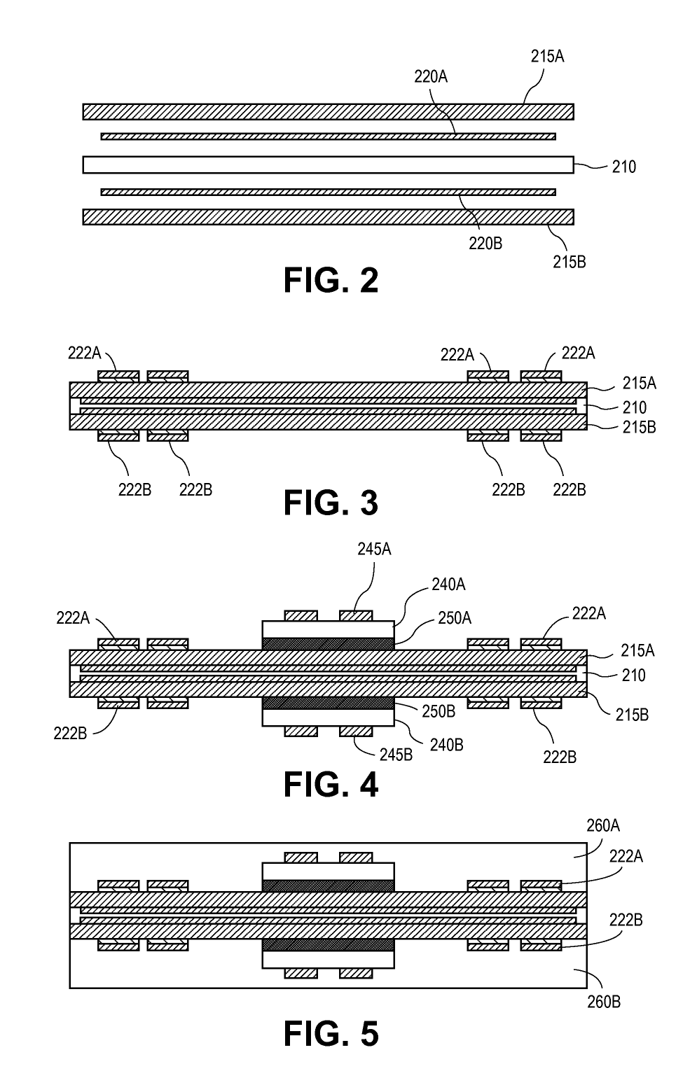

FIG. 2 illustrates an initial process for forming a microelectronic package, such as microelectronic package 100 (FIG. 1). Referring to FIG. 2, FIG. 2 shows an exploded cross-sectional side view of a portion of sacrificial substrate 210 of, for example, a prepeg material including opposing layers of copper foils 215A and 215B that are separated from sacrificial substrate 210 by shorter copper foil layers 220A and 220B, respectively. Copper foils 215A and 215B tend to stick to the shorter foils based on vacuum. In one embodiment, overlying a surface of copper foils 215A and 215B (a surface opposing copper foils 220A and 220B) is a dielectric material of, for example, ABF, having a thickness on the order of 10 to 100 microns.

FIG. 3 shows the structure of FIG. 2 following the introduction and patterning of contacts on copper foil 215A and copper foil 215B, respectively. FIG. 3 shows contacts 222A and 222B formed on copper foil 215A and 215B, respectively. In one embodiment, contacts 222A and 222B include a first layer adjacent copper foil 215A and copper foil 215B, respectively, of a gold-nickel alloy and a second layer overlying a second layer of copper or a copper alloy overlying the gold-nickel alloy. Contacts 222A and 222B may be formed by deposition (e.g., plating, a sputter deposition, etc.) and patterning at a desired location for possible electrical contact with a secondary device or package.

FIG. 4 shows the structure of FIG. 3 following the mounting of die 240A and die 240B on opposite sides of the structure. As shown in FIG. 4, die 240A is connected by DBF 250A and die 240B is connected by DBF 250B. A suitable material for DBF 250A and DBF 250B is a material that provides a marking contrast of at least 20 percent. Representative material was described with reference to FIG. 1. In one embodiment, DBF 250A and DBF 250B are introduced on die 240A and die 240B to a thickening on the order of 30 microns, respectively, by wafer level lamination.

Referring to FIG. 4, die 240A and die 240B are positioned device side up (device side facing away from each copper foil). On a device side of each die, conductive pillars 245A and 245B are connected to the contact points of die 240A and die 240B, respectively. Pillars 245A and pillars 245B may be fabricated at the die fabrication stage.

FIG. 5 shows the structure of FIG. 4 following the introduction of a dielectric layer on each side of the structure. FIG. 5 shows dielectric layer 260A and dielectric layer 260B. In one embodiment, dielectric layer 260A and dielectric layer 260B are each an ABF dielectric material possibly including a filler that have been described for use in forming a BBUL package. One method of introduction of an ABF material is as a film that is laid on the respective dice, the contacts and copper foils.

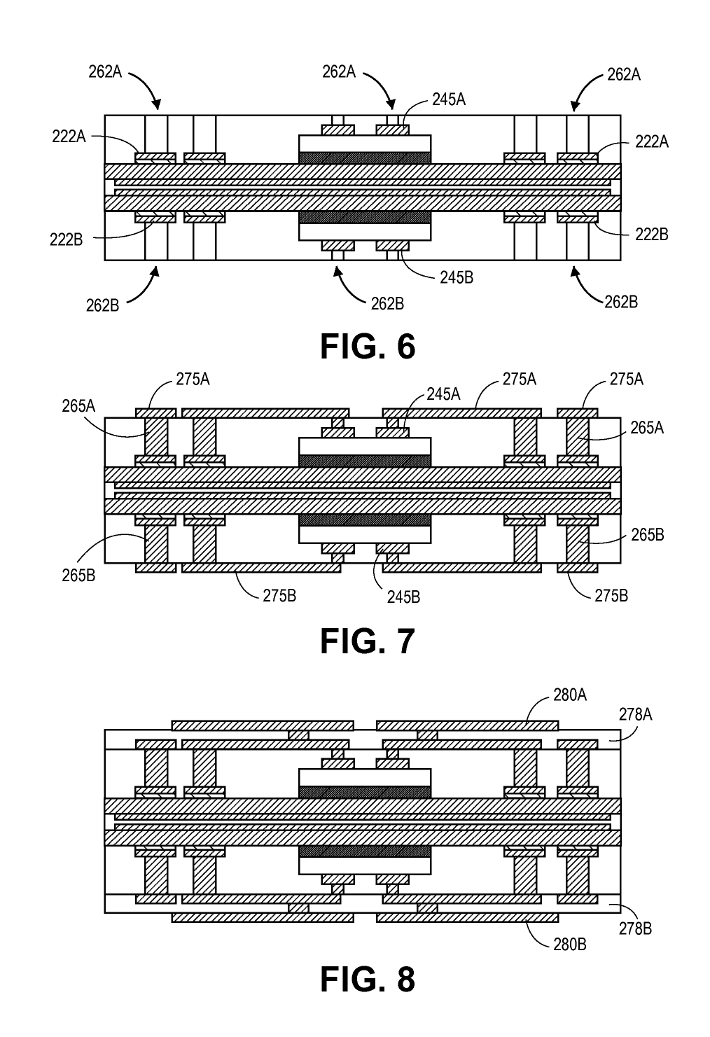

FIG. 6 shows the structure of FIG. 5 following the opening of vias 262A and 262B in dielectric layer 260A and dielectric layer 260B to contacts 222A, contacts 222B, pillars 245A and pillars 245B. In one embodiment, such openings or vias may be achieved by a laser process.

FIG. 7 shows the structure of FIG. 6 following the patterning of a conductive line or layer 275A and conductive line or layer 275B on dielectric layer 260A and dielectric layer 260B, respectively, and conductive vias 265A and 265B formed through the respective dielectric layers to contacts 222A and contacts 222B, respectively. Conductive vias are also formed to pillars 245A and pillars 245B to contact points on a device side of die 240A and die 240B. A suitable material for patterned conductive line or layer 275A/275B and for conductive vias 265A/265B is copper deposited, for example, by an electroplating process.

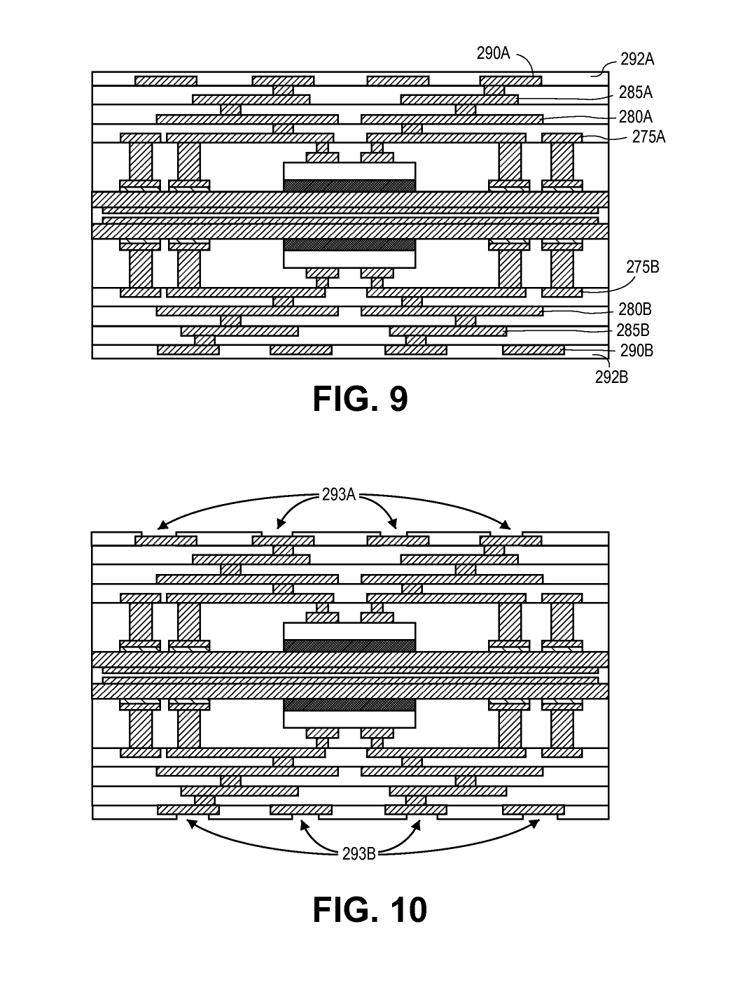

FIG. 8 shows the structure of FIG. 7 following the patterning of an additional level of conductive line or layer of a carrier. FIG. 8 shows conductive line or layer 280A and conductive line or layer 280B separated from conductive line or layer 275A and 275B, respectively by dielectric layer 278A and 278B, respectively (e.g., an ABF film). A typical BBUL package may have four to six levels of conductive lines or traces similar to conductive lines or layers 275A, 275B, 280A and 280B separated from adjacent lines by dielectric material (e.g., ABF film). Connections between the layers are made, in one embodiment, by conductive vias (e.g., copper filled vias) formed by laser drilling the vias and depositing a conductive material in the vias. FIG. 9 shows the structure following the introduction and patterning of conductive lines or layers 285A and 285B (third level) and conductive lines or layers 290A and 290B (fourth level). In this embodiment, conductive lines or layers 290A and 290B are an ultimate or top level of the carrier body. FIG. 9 also shows dielectric material 292A and dielectric material 292B on, for example, an ABF laminated film overlying conductive layer or lines 292A and 292B, respectively. In one embodiment, conductive lines or layers 290A and 290B are patterned into lands or pads for a packaging implementation.

FIG. 10 shows the structure of FIG. 9 following the formation of openings to respective ones of the conductive pads that define conductive layers or lines 290A and 290B. In one embodiment, opening 293A and opening 293B are formed by a laser via process.

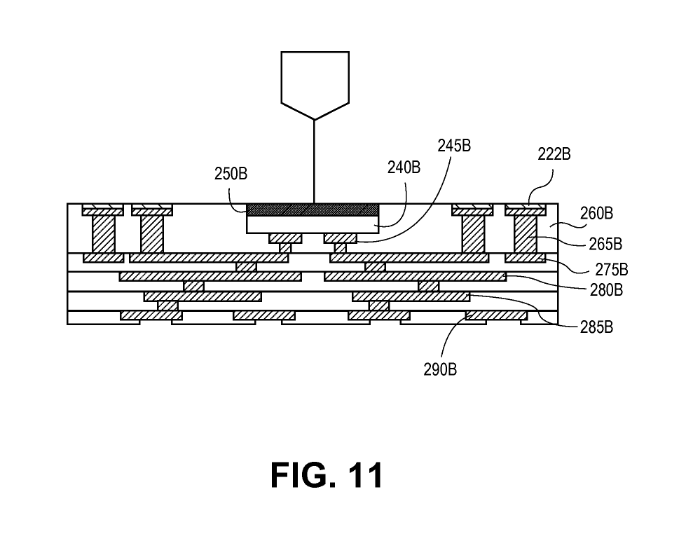

FIG. 11 shows a portion of the structure of FIG. 10 following the separation of the structure into two individual package portions by removal of sacrificial substrate 210 and copper foils 215A and 215B.

In one embodiment, the structure is separated from sacrificial substrate 210, copper foils 215A and 215B, and copper foils 220A and 220B by a wet blast process. In one embodiment, a wet blast process includes multiple passes of an etchant (e.g., an etchant of one or more of the following: aluminum, titanium, silicon oxides). A first pass may separate copper foils 215A and 215B from copper foils 220A and 220B, respectively, leaving die 240A and die 240B connected to copper foils 215A and 215B, respectively, through DBF 250A and 250B. A second wet blast process pass may then be used to remove copper foils 215A and 215B from DBF films 250A and 250B, respectively. Where a dielectric material is present on the copper foils prior to introduction of DBF 250A and DBF film 250B, a wet blast process may be used to remove the dielectric material from the DBF. Such process may take on the order of 40 to 50 passes to remove a dielectric material like ABF from DBF 250A and DBF 250B. It has surprisingly been found that a DBF film material including nanometer sized filler particles, such as silica particles of 50 nanometers or less, is more resistant to removal by a wet blast process than DBF films including micrometer sized filler particles. Accordingly, a DBF film including nano sized particles has greater selectivity than a DBF film including micrometer sized filler particles relative to a wet blast process.

By removing the individual package portions from sacrificial substrate 210, FIG. 11 shows a portion of a free standing microelectronic package that has a die connected at a device side to a build-up carrier including a number of alternating layers of electrically conductive material (four levels of conductive traces) and dielectric or insulating material. Conductive pillars 245B fabricated, for example, at the die fabrication process are connected to contact points on a device side of die 240B and are connected to the conductive material of the build-up carrier. The package also includes contact points 222B extending to a surface of the build-up carrier (upper surface as viewed) for electrical connection to a secondary device (e.g., memory device, logic device) or package (e.g., package containing one or more memory devices, logic devices, memory and logic devices, etc.). In another embodiment, the die may be a through silicon vias (TSV) die. Finally, the package includes a number of conductive posts extending from a second side (bottom side as viewed) that may be used to connect the package to a printed circuit board through, for example, a solder connection.

FIG. 11 also shows a marking operation. Once DBF 250B is exposed, the film may be exposed to an electro magnetic radiation process (e.g., a laser process) wherein the film is marked with an appropriate identification. Such identification may include, but is not limited to, a company logo, a pin orientation, a manufacturing history such as lot number, and/or time/date traceability.

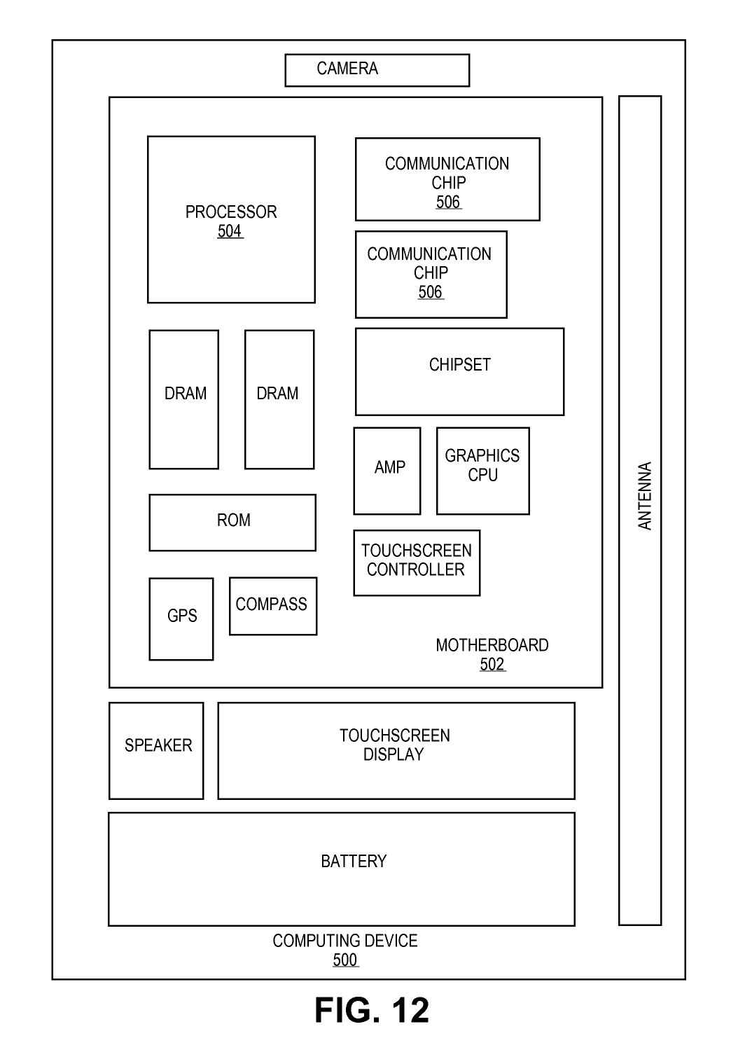

FIG. 12 illustrates a computing device 500 in accordance with one implementation. Computing device 500 houses board 502. Board 502 may include a number of components, including but not limited to processor 504 and at least one communication chip 506. Processor 504 is physically and electrically coupled to board 502. In some implementations the at least one communication chip 506 is also physically and electrically coupled to board 502. In further implementations, communication chip 506 is part of processor 504.

Depending on its applications, computing device 500 may include other components that may or may not be physically and electrically coupled to board 502. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

Communication chip 506 enables wireless communications for the transfer of data to and from computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chip 506 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Computing device 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

Processor 504 of computing device 500 includes an integrated circuit die packaged within processor 504. In some implementations, the package formed in accordance with embodiment described above utilizes BBUL technology with carrier including a body having a die embedded therein and DBF film of a material including a mark contrast of at least 20 percent and, optionally a DBF that is marked with identification information. The term “processor” may refer to any device or portion of a device that processes electronic data from registers and/or memory to transform that electronic data into other electronic data that may be stored in registers and/or memory.

Communication chip 506 also includes an integrated circuit die packaged within communication chip 506. In accordance with another implementation, package is based on BBUL technology and incorporates a primary core surrounding a TSV or non-TSV integrated circuit die that inhibit package warpage. Such packaging will enable stacking of various devices, including but not limited to, a microprocessor chip (die) with a memory die with a graphics die with a chip set with GPS.

In further implementations, another component housed within computing device 500 may contain a microelectronic package that incorporates a primary BBUL carrier implementation such as described above.

In various implementations, computing device 500 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, computing device 500 may be any other electronic device that processes data.

In the description above, for the purposes of explanation, numerous specific details have been set forth in order to provide a thorough understanding of the embodiments. It will be apparent however, to one skilled in the art, that one or more other embodiments may be practiced without some of these specific details. The particular embodiments described are not provided to limit the claims but to illustrate it. The scope of the claims is not to be determined by the specific examples provided above. In other instances, well-known structures, devices, and operations have been shown in block diagram form or without detail in order to avoid obscuring the understanding of the description. Where considered appropriate, reference numerals or terminal portions of reference numerals have been repeated among the figures to indicate corresponding or analogous elements, which may optionally have similar characteristics.

It should also be appreciated that reference throughout this specification to “one embodiment”, “an embodiment”, “one or more embodiments”, or “different embodiments”, for example, means that a particular feature may be included in the practice of the invention. Similarly, it should be appreciated that in the description various features are sometimes grouped together in a single embodiment, figure, or description thereof for the purpose of streamlining the disclosure and aiding in the understanding of various inventive aspects. This method of disclosure, however, is not to be interpreted as reflecting an intention that the invention requires more features than are expressly recited in each claim. Rather, as the following claims reflect, inventive aspects may lie in less than all features of a single disclosed embodiment. Thus, the claims following the Detailed Description are hereby expressly incorporated into this Detailed Description, with each claim standing on its own as a separate embodiment of the invention.

What is claimed is:

1. An apparatus comprising:
a die comprising a first side and an opposite second side comprising a device side with contact points; and
a build-up carrier comprising a body comprising a plurality of alternating layers of conductive material and dielectric material disposed on the second side of the die, and an ultimate conductive layer patterned into a plurality of pads; and
a film disposed on the first side of the die, the film comprising a markable material comprising a mark contrast of at least 20 percent.

2. The apparatus of claim 1, wherein the film comprises silica particles having a mean particle size of 100 nanometers or less.

3. The apparatus of claim 1, wherein the film comprises silica particles having a mean particle size of 50 nanometers.

4. The apparatus of claim 2, wherein the silica particles comprise 20 percent to 50 percent of the total weight of a composition of the film.

5. The apparatus of claim 1, wherein the film comprises a dye material comprising a maximum light absorption in a visible wavelength region.

6. The apparatus of claim 4, wherein the film comprises a base resin and a flexibilizer.

7. A method comprising:
forming a body of a build-up carrier adjacent a device side of a die, the body of the build-up carrier comprising a plurality of alternating layers of conductive material and dielectric material wherein an ultimate conductive layer is patterned into a plurality of pads, wherein at least one of the layers of conductive material is coupled to a device of the die; and
forming a film on a back side of the die, the film comprising a markable material comprising a mark contrast of at least 20 percent.

8. The method of claim 7, further comprising marking the film.

9. The method of claim 8, wherein marking comprises marking with electromagnetic radiation.

10. The method of claim 7, wherein the film comprises silica particles having a particle size of 100 nanometers or less.

11. The method of claim 7, wherein the film comprises silica particles having a mean particle size of 50 nanometers.

12. The method of claim 7, wherein wherein the film comprises a dye material comprising a maximum light absorption in a visible wavelength region.

13. An apparatus comprising:
a package comprising a microprocessor disposed in a carrier,
the microprocessor comprising a first side and an opposite second side comprising a device side,
the carrier comprising a body comprising a plurality of alternating layers of conductive material and dielectric material disposed on the second side of the die, and an ultimate conductive material layer defining a plurality of pads;
a film on the first side of the microprocessor, the film comprising a markable material comprising a mark contrast of at least 20 percent; and
a printed circuit board coupled to at least a portion of the plurality of conductive posts of the carrier.

14. The apparatus of claim 13, wherein the film comprises silica particles having a mean particle size of 100 nanometers or less.

15. The apparatus of claim 13, wherein the film comprises silica particles having a mean particle size of 50 nanometers.

16. The apparatus of claim 15, wherein the silica particles comprise 20 percent to 50 percent of the total weight of a composition of the film.

17. The apparatus of claim 13, wherein the film comprises a dye material comprising a base resin and a flexibilizer.

18. The apparatus of claim 13, wherein the film comprises a maximum light absorption in a visible wavelength region.
